(19) United States
(12) Patent Application Publication
(10) Pub. No.: US 2017/0169998 A1
(43) Pub. Date: Jun. 15, 2017

(54) In-Cu Alloy Sputtering Target And Method For Producing The Same

(71) Applicant: JX Nippon Mining & Metals Corporation, Tokyo (JP)

(72) Inventors: Yosuke Endo, Ibaraki (JP); Ryo Suzuki, Ibaraki (JP); Tomoji Mizuguchi, Ibaraki (JP); Hiroshi Takamura, Ibaraki (JP)

(21) Appl. No.: 15/371,289

(22) Filed: Dec. 7, 2016

(30) Foreign Application Priority Data
Dec. 11, 2015 (JP) 2015-242674

(51) Int. Cl. H01J 37/34; C23C 14/34

(52) U.S. Cl. CPC H01J 37/3429; C23C 14/3414; H01J 2237/332

(57) ABSTRACT

The purpose of the present invention is to provide an In—Cu alloy sputtering target member having high compositional homogeneity in the thickness direction. The present invention provides a sputtering target member having a composition containing from 1 to 70 at. % of Cu relative to a total number of atoms of In and Cu, the balance being In and inevitable impurities, wherein the target member fulfills 0.95≦A/B≦1, where A represents a Cu atomic concentration relative to the total number of atoms of In and Cu in one half of a thickness direction; B represents a Cu atomic concentration relative to the total number of atoms of In and Cu in the other half of the thickness direction; and B≧A; and wherein a number of pores having a size of 100 μm or more is less than 10/cm² on average.

### TECHNICAL FIELD

The present invention relates to an In—Cu alloy sputtering target. This invention also relates to a method for producing the In—Cu alloy sputtering target.

### BACKGROUND ART

Indium is used as a sputtering target material for forming light-absorbing layers of Cu—In—Ga—Se-based (CIGS based) and Cu—In—Se-based (CIS based) thin film solar cells. Conventionally, in steps of forming these light-absorbing layers, a pure In sputtering target was used to form a pure In film. However, recently, it has been proposed that an In—Cu alloy sputtering target has been used in place of the pure In spattering target, in order to improve sputtering properties and film properties.

Japanese Patent Application Public Disclosure (KOKAI) No. 2012-079997 (Patent Document 1) discloses a problem that when the pure In film is formed by the sputtering method, discontinuous layers will be formed by deposition of In crystalline in the form of island, for example, when the pure In film is laminated on a Cu—Ga alloy film, parts that are coated and those that are not coated with the pure In will be formed. This document discloses that when producing the light-absorbing layer for solar cells by the sputtering method, an In—Cu alloy film is used in place of the conventional pure In film to obtain a continuous In—Cu alloy film rather than the island-shaped In film. It also discloses that a light-absorbing layer having uniform composition in the same plane and good film properties (i.e., good in-plane homogeneity) can be formed with high productivity and high reproducibility. Then, this document proposes a sputtering target for use in the production of light-absorbing layers for compound semiconductor thin-film solar cells, comprising Cu; at least one element selected from the group consisting of In, Ga and Al; and Se, wherein it contains from 30 to 80 atomic % of Cu, the balance being In and inevitable impurities.

Although Patent Document 1 does not mention any method for producing a sputtering target, Japanese Patent Application Pubic Disclosure (KOKAI) No. 2012-052190 (Patent Document 2) discloses a method for producing an indium-based sputtering target by a melting and casting method. Also known are a thermal spraying method in which metal powders for a target material is thermal-sprayed to a backing tube; a compression molding method by cold isostatic pressing (CIP method) which is conducted in a state that metal powders for a target material is arranged in close contact with the backing tube so as to surround its outer peripheral surface (e.g., Japanese Patent Application Public Disclosure (KOKAI) No. 2015-017297 (Patent Document 3)); and the like.

### PRIOR ART DOCUMENT

Patent document 1: JP2012-079997

Patent Document 2: JP2012-052190

Patent Document 3: JP2015-017297

### SUMMARY OF INVENTION

### Problem to be Solved by the Invention

The In—Cu alloy sputtering target is expected to be applied to formation of the light-absorbing layers for the thin film solar cells. However, Patent Document 1 neither mentions its producing method nor discusses properties given to the sputtering target by the producing method. The present inventors have found that when producing the In—Cu alloy sputtering target containing a high concentration of Cu as described in Patent Document 1 by the melting and casting method as described in Patent Document 2, variation in the copper concentration is generated in the thickness direction. Such variation in the composition is approximately from 4 to 5 at. % in terms of difference in Cu concentrations, but in light of the whole target life, there is a risk that variation in the composition of film is generated, thereby preventing from obtaining a sputtered film having a stable quality.

Further, the thermal spraying method and CIP method described in Patent Document 3 are not likely to generate the variation in composition in the thickness direction of the target material. However, both sputtering targets produced by these methods cause problems that it is difficult to increase the relative density because gases penetrate into the targets and pores cannot be completely crushed, and that targets tend to increase the oxygen concentration because the raw materials used in the thermal spraying and CIP methods are fine powders. If the oxygen concentration is higher, a higher number of oxides will be present in the target. Accordingly, the performing of high power sputtering for increasing the deposition rate of the sputter to improve the productivity of the solar cell may generate arcing starting from high-resistant oxides and particles caused thereby, resulting in degraded film quality. Additionally, if the pores are present inside the target, the arcing will be readily generated.

The present invention has been made in view of the above circumstances, and one of the objects is to provide an In—Cu alloy sputtering target member having high compositional homogeneity in the thickness direction. Another object of the present invention is to provide a method for producing such an In—Cu alloy sputtering target member, which can improve the compositional homogeneity in the thickness direction.

### Means for Solving the Problem

The present inventors have studied the reason why the composition distribution is generated in the In—Cu alloy sputtering target member produced by the melting and casting method, and found that during the melting and casting of In and Cu which are raw materials, the solid phase fraction having a relatively high specific gravity (typically Cu—In compound) precipitates during the solidification process, so that the Cu concentration in the lower part is increased, and/or the Cu concentration in the part undergoing the high cooling speed is increased. Accordingly, the present inventors have extensively studied an approach for mitigating such phenomena, and found that a method of mechanically stirring the raw material in a sufficient manner when it is in a molten state and in a semi-molten state is useful. Although the operation itself for stirring the molten metal can also be carried out in the conventional melting and casting method, it is important that in the production of the In—Cu alloy sputtering target member, a sufficient stirring in the semi-molten state is carried out until it reaches a predetermined solid phase rate, in order to produce the target member having a highly uniform composition in the thickness direction.

In one aspect, the present invention completed on the basis of the above findings is a sputtering target member having a composition comprising from 1 to 70 at. % of Cu relative to the total number of atoms of In and Cu, the balance being In and inevitable impurities, wherein the target member fulfills 0.95≦A/B≦1, where A represents a Cu atomic concentration relative to the total number of atoms of In and Cu in one half of the thickness direction; B represents a Cu atomic concentration relative to the total number of atoms of In and Cu in another half of the thickness direction; and B≧A; and wherein the number of pores having a size of 100 μm or more is less than 10/cm² on average.

In one embodiment of the sputtering target member according to the present invention, an oxygen concentration is 100 ppm by mass or less.

In one embodiment of the sputtering target member according to the present invention, an oxygen concentration is 50 ppm by mass or less.

In another embodiment of the sputtering target member according to the present invention, a thickness is 10 mm or more.

In another aspect, the present invention is a sputtering target wherein the sputtering target member according to the present invention is bonded onto a backing plate.

In a further aspect, the present invention is a method for producing a sputtering target member, comprising casting a raw material having a composition comprising from 1 to 70 at. % of Cu relative to the total number of atoms of In and Cu, the balance being In and inevitable impurities, via a step of cooling the raw material with mechanically stirring under a nitrogen atmosphere throughout two states from a molten state to a semi-molten state.

In one embodiment of the method for producing the sputtering target member according to the present invention, said stirring is terminated when the temperature is in a range of 160 to 175° C. for the Cu concentration of 1 at. % or more and less than 31 at. %, or when the temperature is such that a solid phase rate is from 40 to 50% for the Cu concentration range of from 31 to 70 at. %, relative the total number of atoms of In and Cu.

In another embodiment of the method for the sputtering target member according to the present invention, a semi-product in the semi-molten state after terminating said stirring is cooled at a cooling speed of 1° C./s or more.

### Effects of the Invention

The present invention allows an In—Cu alloy sputtering target member having high compositional homogeneity in the thickness direction to be provided. Therefore, it enables to obtain a sputtered film having a stable quality with decreased variation of the composition throughout the target life. Further, in one embodiment, the In—Cu alloy sputtering target member according to the present invention is substantially free of pores and can have at the same time a lower oxygen concentration, and thus in this case, it is expected that a stable sputtering step with limited generation of arcing can be carried out.

### BRIEF DESCRIPTION OF DRAWINGS

FIG. 1 is a schematic diagram of a high frequency induction furnace used in Examples.

FIG. 2 is a schematic diagram showing measuring points of atomic concentrations of Cu in one half and the other half in the thickness direction.

FIG. 3 is examples of SEM photographs showing states of pores in the inventive product (Example 3) and comparative product (Comparative Example 4).

FIG. 4 is a schematic sectional view showing an example of a stirring blade configuration in the case of producing a cylindrical shaped sputtering target.

### MODES FOR CARRYING OUT THE INVENTION

(Composition)

In one embodiment, the sputtering target member according to the present invention has a composition comprising from 1 to 70 at. % of Cu relative to the total number of atoms of In and Cu, the balance being In and inevitable impurities.

The inevitable impurities refer to impurities that may be present in raw materials or inevitably mixed during producing steps, and that are not necessary per se, but are acceptable because they are in a miner amount, thereby having no effect on properties of metal products. The total mass concentration of the inevitable impurities excluding oxygen is preferably 100 ppm by mass or less relative to the total mass of In and Cu, and more preferably 80 ppm by mass or less, and even more preferably 50 ppm by mass or less. Examples of the inevitable impurities include Fe, Ni, Cr and the like. Oxygen is also one of the inevitable impurities, which will be defined separately.

In one embodiment, the sputtering target member according to the present invention is such that when measuring Cu atomic concentrations relative to the total number of atoms of In and Cu in one half and the other half obtained by bisection along a cutting line perpendicular to the thickness direction, they can fulfill the condition: 0.95≦A/B≦1, and more preferably 0.96≦A/B≦1, and even more preferably 0.97≦A/B≦1, for example 0.950≦A/B≦0.995, where A is the atomic concentration of Cu relative to the total number of atoms of In and Cu in one half; B is the atomic concentration of Cu relative to the total number of atoms of In and Cu in the other half; on the premise of B≧A.

Here, the Cu atomic concentrations relative to the total number of atoms of In and Cu in one half 31 and the other half 32 in the thickness direction are measured by the following method. As illustrated by the shaded area in FIG. 2, a sampling area is firstly determined (the area may be any place in the plane, but it must be a dimension of 5 mm×5 mm or more in the longitudinal and lateral directions perpendicular to the thickness direction (in the width and depth directions in the figure), taking variation of measured values into account), and collected by cutting its area with a bandsaw or a cutting machine or like, provided that cutting margins can be ignored. It is then cut into two equal parts along the cutting line A-A′ in a direction perpendicular to the thickness direction t to obtain a sampling area 33 of one half 31 and a sampling area 34 of the other half 32. If the thickness is thin and it is difficult to cut it, after the sampling area is determined and collected, the area from one main surface to the A-A′ surface is removed by polishing, grinding and the like to leave the remaining as a sample, for example when one wishes to measure the Cu concentration of the other half 32. The sampling area may be any place in the target, provided that the sample includes one half 31 from one main surface of the target to the A-A′ surface and the other half from the A-A′ surface to the other main surface of the target. The Cu and In concentrations can be determined by ICP analysis.

The shape of the sputtering target member according to the present invention is not particularly limited, but can be a flat plate shape such as a disk shape and a rectangular flat plate shape, and further a cylindrical shape. The thickness direction refers to a plate thickness direction when the sputtering target member is in the form of the flat plate such as the disk and the rectangular flat plate, and a radial direction when the sputtering target member is cylindrical.

The higher homogeneity of the Cu concentration in the thickness direction means that the compositional homogeneity in the thickness direction of the In—Cu alloy sputtering target member is higher. It is expected that this provides a sputtered film having a stable quality with decreased variation in the composition throughout the target life.

(Pores)

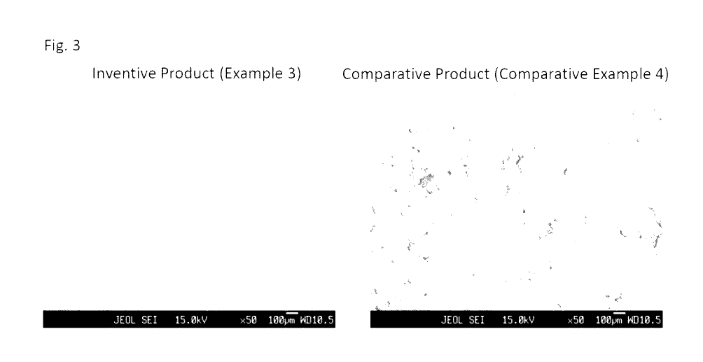

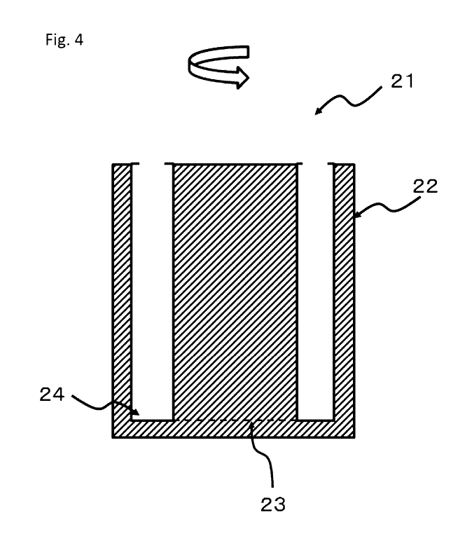

If pores having a size of 100 μm or more are present in the sputtering target member, it will tend to generate splashing or arcing from points around the pores, which will make the sputtering unstable. It is thus desirable that the sputtering target has decreased pores having a size of 100 μm or more. In one embodiment of the In—Cu alloy sputtering target according to the present invention, the number of the pores having a size of 100 μm or more is less than 10/cm² on an average, the number of the pores having a size of 100 μm or more is preferably less than 1/cm² on an average, and the number of the pores having a size of 100 μm or more is more preferably 0/cm². FIG. 3 shows metallographic pictures of an In—Cu alloy sputtering target in which pores having a size of 100 μm or more are present (Comparative Example 4) and an In—Cu alloy sputtering target according to Example 3 of the present invention.

In the present invention, the number density of pores having a size of 100 μm or more is determined by observing a sputtering surface of a target to be measured by SEM, counting the number of pores having a size of 100 μm or more and calculating the number density of pores from the area of the sputtering surface of the target to be measured. Here, the size of the pore is defined by a diameter of the smallest circle surrounding the pore. The viewing field for measurement is arbitrary 2 mm square, five or more positions are measured, and their measurements are averaged.

(Oxygen Concentration)

The decreased oxygen concentration of the sputtering target member allows generation of arcing starting from a high-resistant oxide and generation of particles caused thereby to be reduced. In one embodiment, the sputtering target member according to the present invention can have an oxygen concentration of 100 ppm by mass or less, and preferably 50 ppm by mass or less, and more preferably 30 ppm by mass or less, and even more preferably 20 ppm by mass, for example from 10 to 100 ppm by mass.

In the present invention, the “oxygen concentration” in the sputtering target member is determined by an analysis with an inert gas fusion infrared absorption method. In Examples, TC-600 model from LECO Corporation was used.

(Producing Method)

Suitable examples of a method for producing the sputtering target member according to the present invention are now described in order. First, indium and copper, which are raw materials, at a desired mixing ratio are molten in a furnace in an inert atmosphere or under vacuum, and the raw material in a molten state (molten metal) is poured into a mold. A stirring action such as an electromagnetic stirring may be further applied in the melting furnace during the step of melting. Indium and copper used as raw materials preferably have the high degree of purity because if the raw materials contain impurities, there is a risk that a conversion efficiency for a solar cell manufactured by their raw materials would be lowered. For example, one can use raw materials having high purity in which impurities other than oxygen are 100 ppm by mass or less and the oxygen concentration is 100 ppm by mass or less, and preferably raw materials having high purity in which impurities other than oxygen are 50 ppm by mass or less and the oxygen concentration is 50 ppm by mass or less.

It is desirable that the melting temperature is adjusted depending on the amount of Cu added, in terms of complete melting of the raw materials. In one embodiment of the present invention, based on the phase diagram, the melting temperature may be a temperature higher than the melting point of each composition by 100° C. or more, and more preferably by 200° C. or more. However, since too high melting temperature wastes energy costs, the melting temperature is preferably a temperature higher than the melting point of each composition by 400° C. or less, and more preferably by 300° C. or less.

After the molten metal is poured into the mold which has been heated to the melting temperature, the temperature is gradually decreased with stirring. As the temperature decreases, the raw material solidifies, starting from a molten state, increasing a sold phase rate and via a semi-molten state. In order to improve the compositional homogeneity in the thickness direction of the resulting ingot, it is important to cool the molten metal with mechanically stirring throughout two states from the molten state to the semi-molten state. The semi-molten state refers to a state where a solid phase and a liquid phase are intermixed. Typically, at a temperature range from the liquid phase line of the phase diagram to 156.6° C., which is a melting point of In, the material can be in the semi-molten state because in this case, In is in the liquid phase.

The stirring is preferably carried out under conditions that can suppress precipitation of a Cu—In compound with a relatively high specific gravity, throughout the two states from the molten state to the semi-molten state. Further, the stirring is preferably carried out under conditions that can suppress concentration of Cu near the external surface of the raw material or at parts contacted with a coolant where the cooling speed tends to increase.

As the stirring conditions fulfilling such requirements, the rotating speed of the stirring is preferably set to 30 to 60 rpm. Too high rotating speed may result in involvement of slag derived from an oxide film on the surface of the raw materials floating on the surface of the molten metal, etc., and may increase the oxygen concentration. Further, a plurality of stirring blades may be provided depending on the shape of the mold. In the case of the cylindrical target, for example, the stirring blades 21 in a generally U-shape as shown by FIG. 4 can be used to stir the molten metal 24 filled in a gap between the mold 22 and the mold core 23.

Although the stirring is preferably continued as long as possible in order to improve the compositional homogeneity, if the solid phase rate is too high, the stirring will become difficult and the removing of the stirring blades will also become difficult. Therefore, it is desirable that prior to too high solid phase, the stirring be stopped and the stirring blades be removed from a semi-molten solidified slurry. More specifically, the timing for stopping the stirring and removing the stirring blades from the semi-molten solidified slurry can be determined depending on the Cu concentration. In the rage of Cu concentration of 1 at. % or more and less than 31 at. % relative to the total number of atoms of In and Cu, the indium phase having a lower melting point of 156.6° C. is present at a higher fraction, and so the stirring blades are preferably removed when it is in the range of 160 to 175° C., and more preferably in the range of 160 to 170° C., and even more preferably in the range of 160 to 165° C. When the Cu concentration is 31 to 70 at. %, the stirring blades are preferably removed at a temperature where the solid phase rate estimated from the phase diagram is from 40 to 55%, and more preferably at a temperature where the solid phase rate is from 45 to 55%, and even more preferably at a temperature where the solid phase rate is from 50 to 55%.

After removing the stirring blade, quenching may be performed from the semi-molten state to the solidification (the timing passing through 156.6° C. which is the melting point of indium).

It is desirable that, during the stirring of the raw materials, the inside of furnace be under an inert atmosphere, for example, a nitrogen atmosphere, a rare gas atmosphere (argon, helium, neon and the like), or vacuum atmosphere, in order to decrease the oxygen concentration in the resulting sputtering target member.

After the end of stirring, a semi-product in the semi-molten state after the end of stirring is preferably rapidly cooled in order to reduce variation in the composition. If it is left in the semi-molten state as it is, there is concern that precipitated Cu—In compounds may be settled. More particularly, the cooling is preferably performed from the temperature just after the end of stirring in the semi-molten state down to 155° C. at a cooling speed of 1° C./s or higher, and more preferably at a cooling speed of 2° C./s or higher, and even more preferably 5° C./s or higher. However, if the cooling speed is too high, shrinkage cavity may be generated. Therefore, the cooling speed is generally 30° C./s or lower, and preferably 25° C./s or lower, and more preferably 20° C./s or lower.

The cooling speed can be controlled by providing a copper plate or a jacket equipped with a cooling water circuit around the mold and adjusting a flow rate of the cooling water or a temperature of the cooling water. The cooling temperature after the end of stirring is calculated by the equation: (a temperature of a semi-product after the end of stirring 155° C.)/(a period of time from a point of time at which the stirring is terminated to a point of time at which the temperature is lowered to 155° C.). After melting and casting, the resulting ingot is optionally subjected to cold rolling, shape forming and surface polishing to provide the sputtering target member.

The sputtering target member obtained by the melting and casting method generally tends to increase variation of the composition in the thickness direction as the thickness increases, for example, the variation in the composition is remarkable when the thickness is 10 mm or more. However, since the present invention exercises ingenuity for the compositional homogeneity, the compositional homogeneity as discussed above can be achieved regardless of the thickness. Therefore, in the present invention, the thickness of the sputtering target member is not particularly limited, and may be set depending on a sputtering apparatus used or operating time for forming a film, if necessary, and is generally from approximately 3 to 30 mm, and typically from approximately 5 to 20 mm.

The sputtering target member thus obtained can be bonded via a boding material onto a backing plate to provide a sputtering target. In addition, as brazing materials, those having a lower melting point than that of indium, for example In—Sn 50 wt % brazing materials can be used. The sputtering target thus obtained can be suitably used as a sputtering target for producing light absorbing layers for CIGS-based or CIS-based thin film solar cells.

Hereinafter, Examples of the present invention will be illustrated, but these Examples are presented in order to provide better understanding of the present invention and its advantages, and in no way intended to limit the present invention.

### EXAMPLES

### Examples 1 to 7

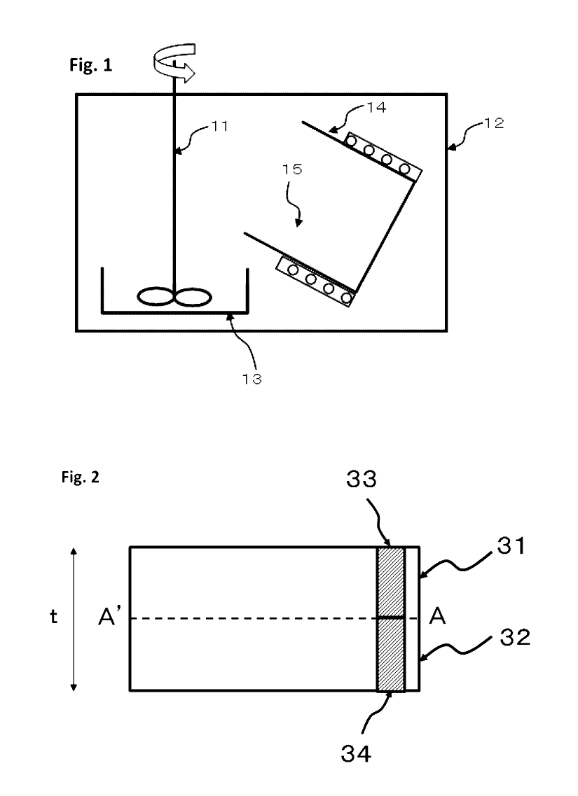

Indium (which had impurities other than oxygen of 100 ppm by mass or less, and oxygen of 100 ppm by mass or less) and copper (which had impurities other than oxygen of 100 ppm by mass or less, and oxygen of 100 ppm by mass or less) as raw materials were provided. Copper was added by each atomic concentration indicated in Table 1 according to each test number (“Average Cu Concentration” in the Table) relative to the total number of atoms of indium and copper to prepare a mixture of indium and copper. Using a high frequency induction furnace 12 having structures indicated in FIG. 1, these raw materials charged in a graphite crucible 14 were heated and molten at 800° C. under a N₂ atmosphere. A molten metal 15 obtained was tapped under a N₂ atmosphere from the crucible 14 into a graphite mold 13 heated at 800° C. which had an inner diameter of 220 mm and a height of 100 mm, such that a thickness of an ingot was 20 mm. The molten metal was then cooled from 800° C. to 165° C. for Examples 1 and 2, and to the temperature at which the solid phase rate is 55% according to the phase diagram for Examples 3 to 7, while stirring the molten metal using a stirring mechanism 11 equipped with stirring blades (parts in contact with the molten metal was made of graphite) piercing the furnace wall under a condition of 30 rpm, with nitrogen flowing. However, Example 5 was stirred at 60 rpm, and Example 6 was stirred at 15 rpm. When a temperature at which the solid phase rate was 55% judging from the phase diagram was reached, the stirring blades were removed, the furnace was opened in the atmosphere, and the mold was then removed and placed onto a copper plate with cooling water channels, and then rapidly cooled to 155° C. at an average cooling speed of 2° C./s to provide an In—Cu alloy ingot. The ingot was then subjected to scraping from the both sides by the same quantity, and processed in the form of a disk having a diameter of 203. 2 mm and a thickness of 10 mm to provide a sputtering target member of each of Examples 1 to 6. In Example 7, a cylindrical target member was produced in a similar manner to Example 1, with the exception that the mold had an inner diameter of 183 mm, a height of 300 mm and a core outer diameter of 127 mm, and the shape of the stirring blades was as shown in FIG. 4. The resulting ingot was then processed such that it had an inner diameter of 135 mm, an outer diameter of 153 mm and a length of 280 mm to provide a sputtering target member.

### Comparative Examples 1 to 4

Indium (which had impurities other than oxygen of 100 ppm by mass or less, and oxygen of 100 ppm by mass or less) and copper (which had impurities other than oxygen of 100 ppm by mass or less, and oxygen of 100 ppm by mass or less) as raw materials were provided. Copper was added by each atomic concentration indicated in Table 1 according to each test number (“Average Cu Concentration” in the Table) relative to the total number of atoms of indium and copper to prepare a mixture of indium and copper, which was then heated and molten at 800° C. under a N₂ atmosphere using the high frequency induction furnace. Each sputtering target of Comparative Examples 1 to 3 was then obtained using the similar procedures to Examples described above, with the exception that the molten metal was cooled without stirring. A sputtering target of Comparative Example 4 was produced by placing a cylindrical mold with no bottom onto an iron plate and rapidly cooling the molten metal by directly pouring it on the iron plate.

### Comparative Example 5

Using the gas atomizing method, In—Cu alloy powders containing the Cu concentration indicated in Table 1 were provided. The average particle diameter of said powders was 106 μm. The powders were cold-pressed under a surface pressure of 30 MPa so as to provide a disk having a diameter of 20 mm and a thickness of 15 mm, and a pressure of 140 MPa was then applied by the CIP method. The obtained green compact was processed into a disk having a diameter of 203.2 mm and a thickness of 10 mm to provide a sputtering target member.

For the In—Cu alloy part of each sputtering target member thus obtained, specimens bisected in the thickness direction by the method as described above were acquired, and Cu concentrations in one half and the other half in the thickness direction of the target were determined using an ICP emission spectrophotometer (model SPS 5520) from SII Nano Technology Inc. Each specimen for determining the Cu concentrations had a rectangular parallelepiped shape of 5 mm×5 mm×4mmt. In addition, during sampling, a sampling loss of about 1 to 2 mm in the thickness direction due to cutting was generated, which was ignored. Also, the number density of pores having a size of 100 μm or more was determined by SEM observation (50 magnifications) on the sputtering surface. Further, the oxygen concentration was measured by the Inert Gas Fusion-Infrared Absorptiometry using TC-600 model from LECO Corporation. Results are shown in Table 1.

<Film Formation Test>

Each sputtering target member obtained was bonded onto a copper backing plate or a backing tube and sputtering was carried out under the conditions described below. The sputtering was continued for two hours, and arcing was counted. Results are shown in Table 2.
Sputtering gas: Ar
Sputtering gas pressure: 0.5 Pa
Sputtering gas flow rate: 25 SCCM
Sputtering temperature: R.T. (no heating)
Input sputtering power density: 1.5 W/cm²
Substrate: Eagle 2000 from Corning Inc., φ 4 inch×0.7 mmt.

Incidentally, the cylindrical target was under similar conditions, with the exception that the power density was 0.6 kW/m.

Moreover, immediately after the start of sputtering and after the end of sputtering, the compositions of the sputtered films were determined by the ICP emission spectrometry for the Cu concentration comparison. Results are shown in Table 2.

| | | | | | | | | | Number Density |
|---|---|---|---|---|---|---|---|---|---|
| | | | Stirring | | | Cu | Concen- | | of Pores |
| | Pro- | | Rotation | Average Cu | Cu | Concentration B | tration | Oxygen | Having Size of |
| | ducing | | Speed | Concentration | Concentration A | in the Other Half | Ratio | Concentration | 100 um or more |
| | Method | Shape | [rpm] | [at %] | in One Half [at %] | [at %] | A/B | [ppm by mass] | [Number/cm²] |
| Example 1 | Stirring | Disk | 30 | 10 | 9.8 | 10.2 | 0.961 | 50 | 0 |
| | Casting | | | | | | | | |
| Example 2 | Stirring | Disk | 30 | 30 | 28.5 | 30.5 | 0.967 | 50 | 0 |
| | Casting | | | | | | | | |
| Example 3 | Stirring | Disk | 30 | 50 | 49.6 | 50.3 | 0.986 | 50 | 0 |
| | Casting | | | | | | | | |
| Example 4 | Stirring | Disk | 30 | 70 | 69.7 | 70.3 | 0.991 | 50 | 0 |
| | Casting | | | | | | | | |
| Example 5 | Stirring | Disk | 60 | 50 | 49.7 | 50.2 | 0.990 | 100 | 9 |
| | Casting | | | | | | | | |
| Example 6 | Stirring | Disk | 15 | 50 | 49.5 | 50.5 | 0.980 | 20 | 0 |
| | Casting | | | | | | | | |
| Example 7 | Stirring | Cylinder | 30 | 50 | 49.5 | 50.5 | 0.980 | 50 | 0 |
| | Casting | | | | | | | | |
| Comparative | Casting | Disk | — | 30 | 28.0 | 32.2 | 0.870 | 50 | 0 |
| Example 1 | | | | | | | | | |
| Comparative | Casting | Disk | — | 50 | 48.0 | 51.9 | 0.925 | 50 | 0 |
| Example 2 | | | | | | | | | |
| Comparative | Casting | Disk | — | 80 | 78.2 | 82.4 | 0.949 | 50 | 0 |
| Example 3 | | | | | | | | | |
| Comparative | Rapid | Disk | — | 50 | 49.7 | 50.2 | 0.990 | 100 | 422 |
| Example 4 | Cooling | | | | | | | | |
| Comparative | OTP | Disk | — | 50 | 49.5 | 49.9 | 0.992 | 800 | 1250 |
| Example 5 | | | | | | | | | |

TABLE 2

| | Difference in Film | |
|---|---|---|
| | Composition (Cu Concen- | |
| | tration) Between Initial | Arcing |
| | Stage and Life End Point | [frequency/h] |
| Example 1 | ≦1.0 at % | 0 |
| Example 2 | ≦1.0 at % | 0 |
| Example 3 | ≦1.0 at % | 0 |
| Example 4 | ≦1.0 at % | 0 |
| Example 5 | ≦1.0 at % | 0 |
| Example 6 | ≦1.0 at % | 0 |
| Example 7 | ≦1.0 at % | 0 |
| Comparative | >1.0 at % | 0 |
| Example 1 | | |
| Comparative | >1.0 at % | 0 |
| Example 2 | | |
| Comparative | >1.0 at % | 0 |
| Example 3 | | |
| Comparative | ≦1.0 at % | 3 |
| Example 4 | | |
| Comparative | ≦1.0 at % | 10 |
| Example 5 | | |

<Discussion>

It can be seen from the above test results that the sputtering target members of Examples 1 to 7 had high compositional homogeneity in the thickness direction of the In—Cu alloy part. In contrast, the sputtering target members of Comparative Examples 1 to 3 had greater variation in the composition in the thickness direction of the In—Cu alloy part as compared with Examples 1 to 7. Further, in the sputtering target of Comparative Example 4, the compositional homogeneity in the thickness direction of the In—Cu alloy part was high, but it had many pores and arcing was often generated thereby. Comparative Example 5 had high compositional homogeneity, but it had more pores and a high oxygen concentration, and arcing was thus often generated.

### DESCRIPTION OF REFERENCE NUMERALS

11 stirring mechanism

12 high frequency induction furnace

13 graphite mold

14 graphite crucible

15 molten metal

21 stirring blades

22 mold

23 mold core

24 molten metal

31 one half

32 the other half

33 sampling area in one half

34 sampling area in the other half

1. A sputtering target member having a composition containing from 1 to 70 at. % of Cu relative to a total number of atoms of In and Cu, the balance being In and inevitable impurities, wherein the target member fulfills 0.95≦A/B≦1, where A represents a Cu atomic concentration relative to the total number of atoms of In and Cu in one half of a thickness direction; B represents a Cu atomic concentration relative to the total number of atoms of In and Cu in the other half of the thickness direction; and B≧A; and wherein a number of pores having a size of 100 μm or more is less than 10/cm² on average.

2. The sputtering target member according to claim 1, wherein an oxygen concentration is 100 ppm by mass or less.

3. The sputtering target member according to claim 1, wherein an oxygen concentration is 50 ppm by mass or less.

4. The sputtering target according to claim 1, wherein a thickness is 10 mm or more.

5. A sputtering target, wherein the sputtering target member according to claim 1 is bonded onto a backing plate.

6. A method for producing a sputtering target member, comprising casting a raw material having a composition containing from 1 to 70 at. % of Cu relative to a total number of atoms of In and Cu, a balance being In and inevitable impurities, via a step of cooling the raw material with mechanically stirring under a nitrogen atmosphere over two states from a molten state to a semi-molten state.

7. The method for producing a sputtering target member according to claim 6, wherein said stirring is terminated when a temperature is in a range of 160 to 175° C. for Cu concentration of 1 at. % or more and less than 31 at. % relative the total number of atoms of In and Cu, or when a temperature is such that a solid phase rate is from 40 to 50% for Cu concentration range of from 31 to 70 at. % relative the total number of atoms of In and Cu.

8. The method for producing the sputtering target member according to claim 6, wherein a semi-product in the semi-molten state after terminating said stirring is cooled at a cooling speed of 1° C./s or higher.
